(19) United States
(12) Patent Application Publication
(10) Pub. No.: US 2009/0179297 A1
(43) Pub. Date: Jul. 16, 2009

(54) JUNCTION BARRIER SCHOTTKY DIODE WITH HIGHLY-DOPED CHANNEL REGION AND METHODS

(75) Inventors: Eric J. STEWART, Silver Spring, MD (US); Ty R. McNUTT, Columbia, MD (US); Rowland C. CLARKE, Sykesville, MD (US)

Correspondence Address: ROTHWELL, FIGG, ERNST & MANBECK, P.C., 1425 K STREET, N.W., SUITE 800, WASHINGTON, DC, 20005, US

(73) Assignee: NORTHROP GRUMMAN SYSTEMS CORPORATION, Los Angeles, CA (US)

(21) Appl. No.: 12/015,096

(22) Filed: Jan. 16, 2008

(51) Int. Cl. H01L 29/872; H01L 21/329

(52) U.S. Cl. 257/475; 438/478; 257/E29.338; 257/E21.359

(57) ABSTRACT

A junction barrier Schottky device includes a semiconductor substrate with basal, drift, and channel regions doped to a first conductivity type. The channel region is more highly doped than the drift region, and a blocking region doped to a second conductivity type is disposed at least partly around the channel region. A Schottky barrier is formed on and in contact with the channel and blocking regions.

### BACKGROUND OF THE INVENTION

1. Field of the Invention

The present invention relates generally to semiconductor devices, and particularly, but not by way of limitation, to junction barrier Schottky devices having a highly-doped channel region.

2. Discussion of the Related Art

Power conditioning circuits require high-speed, low-loss diodes for several functions including clamp and anti-parallel diodes. These diodes must be able to block high voltage in the reverse direction, have low resistance in the forward direction, and switch on and off as fast as possible to reduce transient switching losses. One of the fastest diodes is the Schottky diode 100 (FIG. 1(a)), which is a majority carrier device and avoids any switching delays associated with minority carrier recombination. Schottky diodes can also have a very low turn-on voltage if the appropriate metal is used. The disadvantage of Schottky diodes is that they can suffer from increased leakage current and premature breakdown in the reverse direction. As shown in FIG. 1(a), the Schottky diode includes a metal barrier 160 formed on a semiconductor substrate with a thick, lightly doped (typically 10¹⁴-10¹⁶ ions cm⁻²) “drift” layer 130. The drift layer can be either n or p type (n is shown by way of example), and is used to drop high voltages gradually across the layer, such that the electric field does not exceed the critical value of the semiconductor. However, due to Schottky barrier lowering at the metal/semiconductor interface 145 (where the field is highest), Schottky diodes often breakdown much sooner and leak excessively compared to p/n junction diodes. As a result, Schottky diodes are not well-suited for high voltage applications.

The Junction Barrier Schottky (JBS) diode attempts to combine the advantages of the Schottky with those of the p/n junction. As shown in FIGS. 1(b) and 1(c), a JBS diode 100 is a Schottky diode with a drift layer 130 surrounded by p/n junctions 150. An n-type drift layer with p⁺ shielding regions is shown by way of example. However, a p-type drift with n⁺ shielding regions could also be used. In the forward direction (FIG. 1(b), positive voltage on anode), the JBS functions similar to a Schottky in that majority carriers are injected across the metal-semiconductor interface 145. This results in low turn-on voltage and fast switching. However, in the reverse direction (1(c), high voltage applied to the cathode) the depletion regions 170 from the surrounding p/n junctions overlap and block high fields from accumulating near the metal semiconductor interface. As a result, excessive leakage from Schottky barrier lowering is prevented. The JBS diode attempts to combine the speed of the Schottky diode and the blocking capability of the p/n junction diode.

The drawback of the conventional JBS diode is that the path for current flow is reduced by the presence of the p⁺ regions. Current at the top must flow through the narrow channel region at the top and then spread out through the rest of the drift layer. This narrow channel region can add a large resistance to the diode, which is undesirable for efficient switching. The p⁺ regions could be placed farther apart to alleviate this problem, but then they will not pinch-off adequately in reverse operation to shield the Schottky junction from premature breakdown. As a result, high-voltage JBS diodes often must accept an increased forward resistance to achieve high voltage operation.

Thus, there exists a need for a JBS diode having low channel resistance and adequate pinch-off in reverse operation.

### SUMMARY OF INVENTION

A first aspect of the present invention addresses the above need by providing a junction barrier Schottky diode device that includes a semiconductor substrate including basal, drift, and channel regions doped with a species of a first conductivity type, and a shielding region doped with a species of a second conductivity type. A Schottky barrier is formed on the semiconductor substrate in contact with the channel and shielding regions, with the drift region being spaced from the Schottky barrier by the channel region, and the shielding region being disposed around at least a portion of the channel region. The dopant concentration in the channel region is higher than a dopant concentration in the drift region. Preferably, the depth of the channel region is greater than the depth of the shielding region, and the bottom portion of the channel region extends laterally beneath the shielding region such that the drift layer is spaced from the shielding region by the channel region. The higher doping between p+ regions offsets the reduced area for current flow, greatly reducing the channel resistance. In fact, this doping can be made from 10 to 100-fold higher than the drift doping, making the channel resistance negligible. In addition, the spacing between the p⁺ regions can be designed such that the reverse blocking is not affected.

In accordance with another aspect of the present invention, a method of making a junction barrier Schottky diode device is provided including the steps of forming basal, drift, and channel regions of a first conductivity type in a semiconductor substrate, forming a shielding region of a second conductivity type in the semiconductor substrate around at least a portion of the channel region, and forming a Schottky barrier on the channel and shielding regions. The step of forming basal, drift and channel regions includes forming the channel region with a dopant concentration higher than a dopant concentration of the drift region. The method preferably also includes forming the channel region such that it has a depth greater than the shielding region and extends laterally between the shielding region and the drift region.

Still other aspects and advantages of the present invention will become readily apparent by those skilled in the art from the following detailed description, wherein it is shown and described preferred embodiments of the invention, simply by way of illustration of the best mode contemplated of carrying out the invention. As will be realized the invention is capable of other and different embodiments, and its several details are capable of modifications in various obvious respects, without departing from the invention. Accordingly, the description is to be regarded as illustrative in nature and not as restrictive.

### BRIEF DESCRIPTION OF DRAWINGS

The invention is best understood from the following detailed description when read in connection with the accompanying drawings. It is emphasized that, according to common practice, the various features of the drawing may not be to scale. On the contrary, the dimensions of the various features are arbitrarily expanded or reduced for clarity. Included in the drawings may be the following figures:

FIG. 1 depicts a prior art (a) Schottky diode, (b) junction barrier Schottky (JBS) diode in forward bias, and (c) a JBS diode in reverse bias;

FIG. 2 depicts a vertical JBS diode of the present invention;

FIG. 3 is a graph showing numerical simulations of reverse leakage current for a conventional Schottky diode, a conventional JBS diode, and the JBS diode of the present invention;

FIG. 4 is a graph showing numerical simulations of the forward current for a conventional Schottky diode, a conventional JBS diode, and the JBS diode of the present invention;

FIG. 5 depicts a vertical JBS diode of the present invention wherein non-Schottky electrodes contact the shielding regions;

FIG. 6 depicts a lateral embodiment of the JBS diode of the present invention; and

FIG. 7 depicts an alternative lateral embodiment of the JBS diode of the present invention.

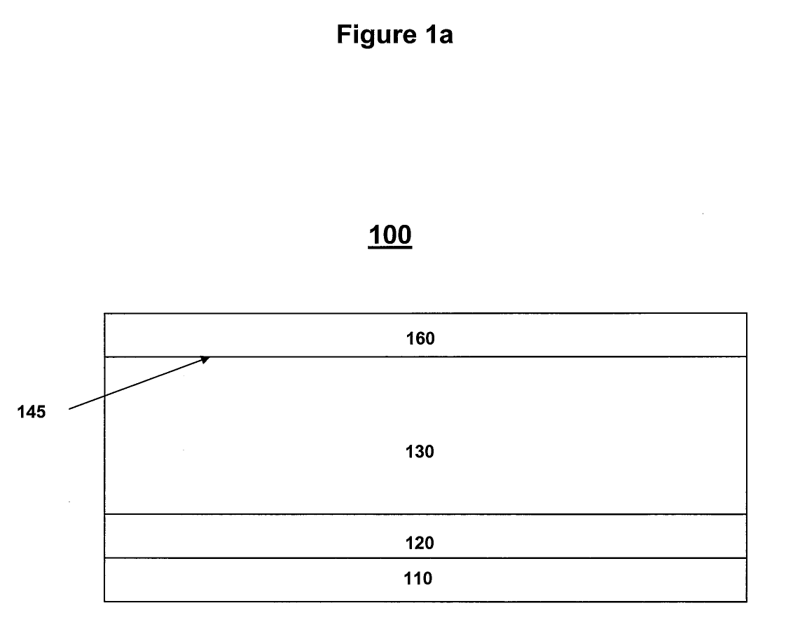

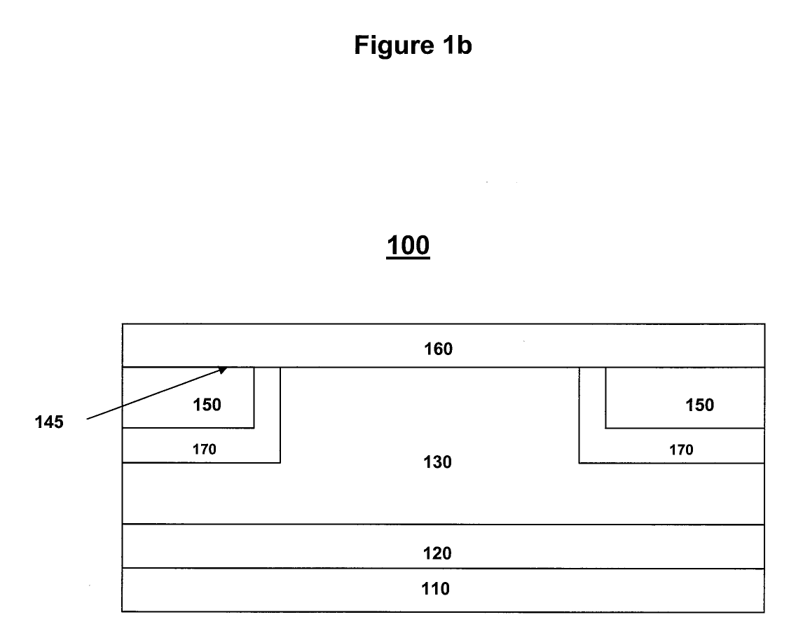

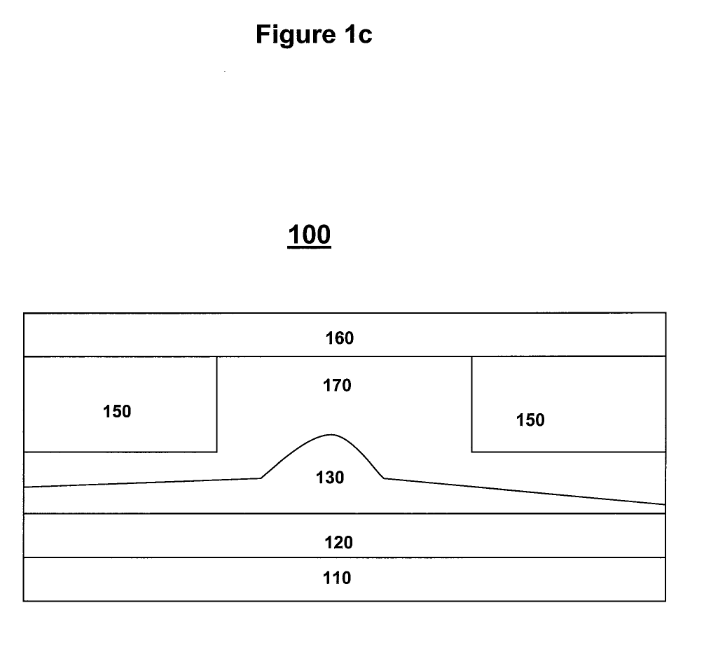

### DETAILED DESCRIPTION OF A PREFERRED EMBODIMENT

Reference is made to the figures to illustrate selected embodiments and preferred modes of carrying out the invention. It is to be understood that the invention is not hereby limited to those aspects depicted in the figures.

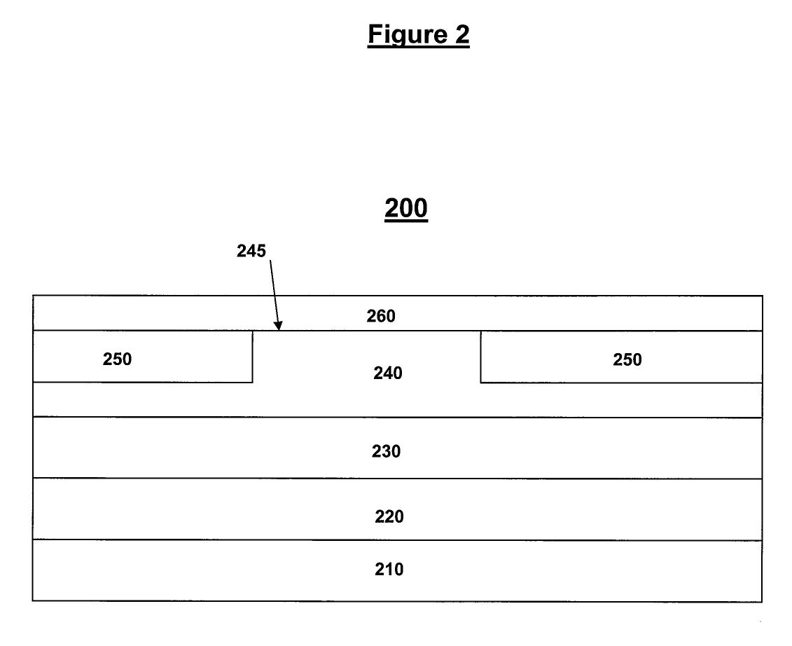

A junction barrier Schottky (JBS) diode 200 according to the present invention is shown in FIG. 2. The JBS diode 200 includes an electrode material 210 and a Schottky barrier 260 on opposite sides of a multi-layer semiconductor substrate having a lightly-doped drift layer 230, a plurality of spaced wells 250, and a highly-doped channel region 240 extending from the Schottky barrier to the drift layer in the space between the wells.

The semiconductor substrate includes a basal layer (region) 220 of first conductivity type adjacent electrode material 210. Preferably, basal layer 220 has first and second, substantially-parallel major surfaces. Layer 220 can be any suitable semiconductor material including, but not limited to, any of germanium (Ge), silicon (Si), gallium arsenide (GaAs), silicon carbide (SiC), indium phosphide (InP), gallium nitride (GaN), and mixtures thereof.

Substrate basal layer 220 is doped with species of a first conductivity type. By way of example, layer 220 is rendered an n-type conductor. Common n-type dopant ions include, but are not limited to, phosphorus (P), nitrogen (N), arsenic (As), and antimony (Sb). When n-doped, layer 220 may be referred to as an n+ layer, or n+ substrate. A preferred dopant concentration is in the range of about 10¹⁸ to about 10¹⁹ ions per cubic centimeter. Commonly, the basal layer is used for mechanical support and is therefore quite thick (hundreds of microns); however, a thin basal layer (e.g., 1 micron) could also be used.

A first major surface of substrate basal layer 220 makes intimate physical contact with an electrode material 210, such that layer 220 and electrode 210 are in ohmic electrical contact.

A second layer of a semiconductor material 230 is formed on a second major surface of substrate basal layer 220. Layer 230 is termed a drift layer. It is understood that drift layer 230 may be formed in various ways using methods known to those skilled in the art. Preferably, drift layer 230 is grown epitaxially on substrate layer 220. However, a layer of semiconductor material equal in thickness to the combined thickness of the substrate and drift may be provided. Subsequently, the layers may be differentiated by differential doping achieved through ion diffusion and/or implantation techniques.

Preferably, the drift layer is of the same semiconductor material as the substrate (but not by way of limitation). Drift layer 230 is doped with ions of the same conductivity type as were used to dope substrate 220. Where n-type ions are used as dopants, layer 230 may be termed an n⁻ layer. The drift layer 230 must be doped to a lower concentration than substrate 220, e.g., at a concentration of from about 10¹⁴ to about 10¹⁵ ions per cubic centimeter. Preferably, drift layer 230 has a major surface 235 substantially parallel to the drift layer-substrate layer interface 215. The thickness of the drift region will depend on the voltage level of the device (and the semiconductor used) but is typically in the 10-100 μm range.

A third layer of a semiconductor material 240 is formed on major surface 235 of drift layer 230. Layer 240 is termed a channel layer. Preferably, the channel layer is of the same semiconductor material as the drift and substrate (but not by way of limitation). Channel layer 240 is of the same conductivity type as for drift layer 230, but the channel dopant concentration is higher than that of the drift layer. Preferably, the channel dopant concentration is from about 10 to about 100 times the dopant concentration in the drift layer. Preferably, channel layer 240 has a major surface that is planar and parallel to the channel—drift interface 235.

A plurality of wells 250 are formed in channel 240. Wells 250 are preferably formed by introducing dopants of a second conductivity type into the semiconductor material of channel 240. In the example, wells 250 are formed by introducing p-type ions. Common p-type dopants include, but are not limited to, boron and aluminum. Preferably, the wells are doped to about 10¹⁸-10²⁰ ions per cubic centimeter. Wells 250 form reverse bias shielding regions.

A plurality of wells 250 are formed extending from major surface 245 towards drift layer 230. Wells 250 are also referred to as shielding regions. In a preferred embodiment, the wells 250 do not extend the full depth of channel 240 and therefore do not touch drift 230, such that the channel extends to a depth greater than that of the wells and extends laterally outward between the wells and the drift layer. The higher doping between the p⁺ regions offsets the reduced area for current flow, greatly reducing the channel resistance. In preferred embodiments, this doping can be up to 100-fold higher than the drift doping, making the channel resistance negligible. In addition, the spacing between the p⁺ regions can be designed such that the reverse shielding is not affected.

Preferably, the channel region is designed to extend at least a small depth beyond the edge of the p+ regions for two reasons. This is preferred for two reasons. First, the area where the current flow is restricted is guaranteed to be highly doped (and thus low resistance) even if variations occur in the epitaxial growth or device processing. Second, the part of the channel that extends below the implants can serve as a current spreading layer to lower the resistance from current having to travel horizontally in the n− drift to funnel into the narrow channel region. In a preferred vertical JBS structure, this layer is built-in automatically.

A Schottky contact 260 is formed on surface 245. Schottky contact 260 is also referred to as a Schottky barrier or Schottky metallization. Schottky contact 260 is in intimate physical contact with at least a portion of channel 240 and with wells 250. Shottky contact 260 may be formed from any suitable Schottky metal including, but not limited to Co, Mo, Al, Ti, Ni, Cr, Mo, Pt, Pd, Zr, W, alloys thereof, and mixtures thereof.

The height of the Schottky barrier may be varied as appropriate to the situation. As is known to persons of skill in the art, judicious selection of the semiconductor material, doping levels, and Schottky metallization may be employed to vary the height of the Schottky barrier.

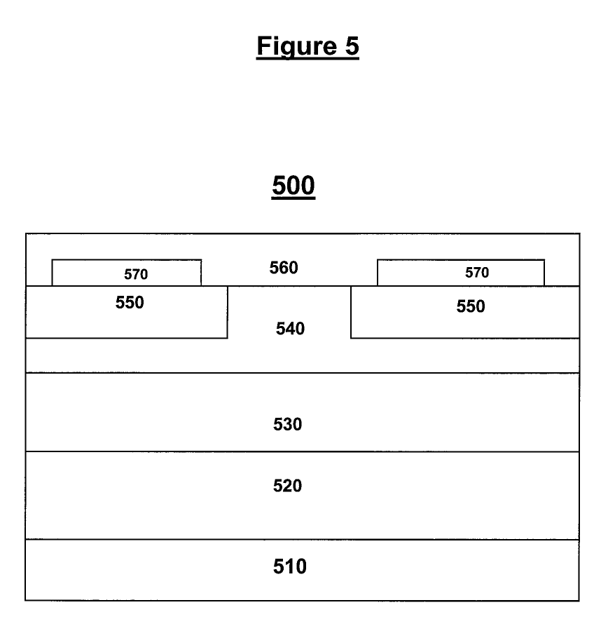

In a preferred embodiment, the Schottky barrier directly contacts the shielding regions. In an alternative embodiment of the JBS diode, shown in FIG. 5 at 500, ohmic contacts 570 are made to the shielding regions 550 (but not to the channel 540) and Schottky metallization 560 is formed over the channel and the ohmic contacts 570. Ohmic cathode 510 is formed under substrate 520.

The present disclosure relates to a preferred embodiment as an n-device. Accordingly, the substrate, drift, and channel regions are illustrated as n-type having, n-dopant ions. Correspondingly, the well regions are illustrated as p-doped. Where a p-type device is desired, the substrate, drift, and channel region dopant will be p-type instead of n-type and it is to be understood herein that all such doped regions may simply be reversed from n- to p-type and p- to n-type to create a p-type device.

In accordance with a preferred embodiment, a JBS diode is provided in which a uniform layer with enhanced n-type doping is provided in and around the p+ regions. This could be formed either using epitaxial growth or through ion-implantation. The n− drift layer, between the channel and the substrate, remains lightly doped to maintain the high breakdown voltage of that layer.

Due to increased doping in the channel compared to the conventional JBS, the depletion regions from the p+ regions will not extend as far. As a result, to pinch-off properly in the reverse direction, the p+ regions must be moved closer together. However, this reduction in channel width is small for two reasons. First, the reduction of depletion width in the channel scales only as approximately the square root of the doping concentration, as can be seen from the expression for an ideal p+/n diode:

$${x}_{d} = \sqrt{\frac{2 ɛ ( {φ}_{bi} + V )}{{qN}_{d}}} \qquad ( 1 )$$

where x_{d} is the depletion width, N_{d} is n-type doping, V is the voltage applied, • is the permittivity of the material, •_{bi} is the built-in potential, and q the electric charge. As a result, if the doping is increased, e.g., by 9×, the channel width will at most have to be decreased by about 3×. However, this is still an overestimate because not all of the “pinching” occurs in the channel. At high reverse voltages, the depletion regions from the p+ regions extend down into the drift layer (where the doping is low) and help pinch-off the channel there. As a result, the difference in channel width can be less than a factor of 2. Since the channel doping is increased by a factor of from 10 to 100-fold, the net result is a 5 to 50-fold reduction in channel resistance.

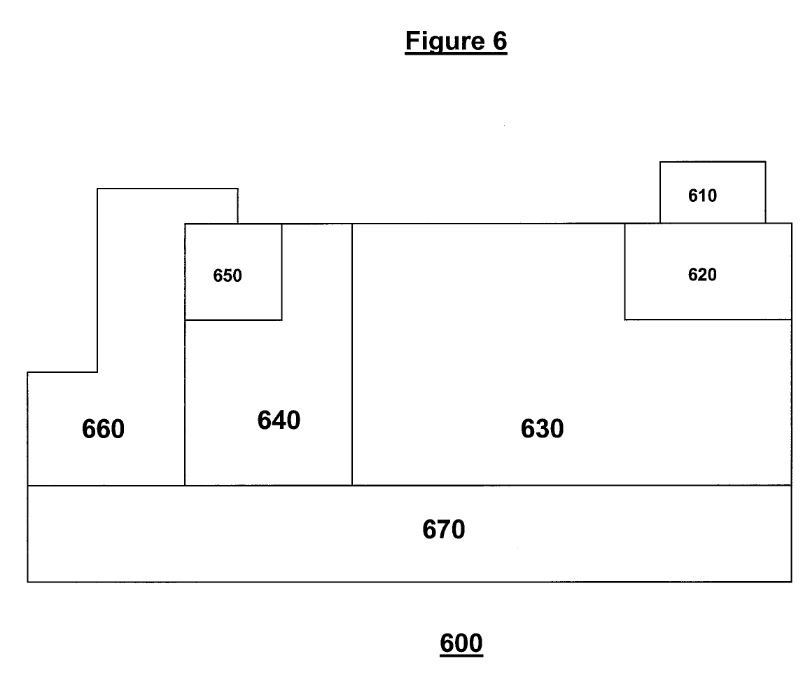

An advantage of the preferred embodiment is that it preserves a vertical current flow path desirable for power switching applications. The JBS device of the present invention may be realized as a structure having a lateral channel. An n-doped embodiment of a lateral JBS diode 600 with a highly doped channel is shown in FIG. 6. Diode 600 comprises a semi-insulating substrate 670, an n⁻ drift region 630, n-channel 640, p⁺ shielding region(s) 650, Schottky anode 660, and an n⁺ region 620 in electrical contact with cathode 610. Preferably semi-insulating substrate 670 is boule-grown. Preferably, channel 640, shielding 650, and contact 620 are formed by ion implantation.

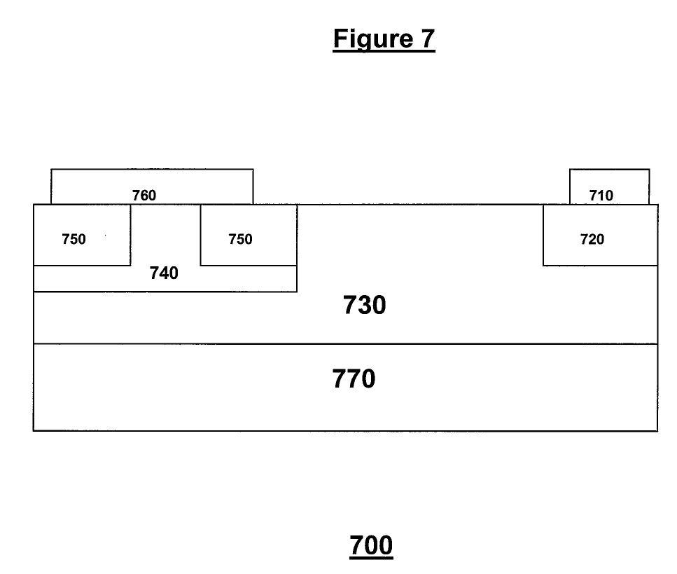

An alternative lateral embodiment is depicted in FIG. 7. Diode 700 comprises a semi-insulating substrate 770, an n⁻ drift region 730, n-channel 740, p⁺ shielding region(s) 750, Schottky anode 760, and an n⁺ region 720 in electrical contact with cathode 710. Preferably semi-insulating substrate 770 is boule-grown. Preferably, channel 740, shielding 750, and contact 720 are formed by ion implantation.

Lateral embodiments are within the scope of the present invention. However, the need for current to flow laterally will increase the forward resistance. Moreover, the fabrication complexity is considerably increased by the need for epitaxial re-growth and multiple mask levels. Moreover, where a lateral device is desired, GaN is a preferred semiconductor material.

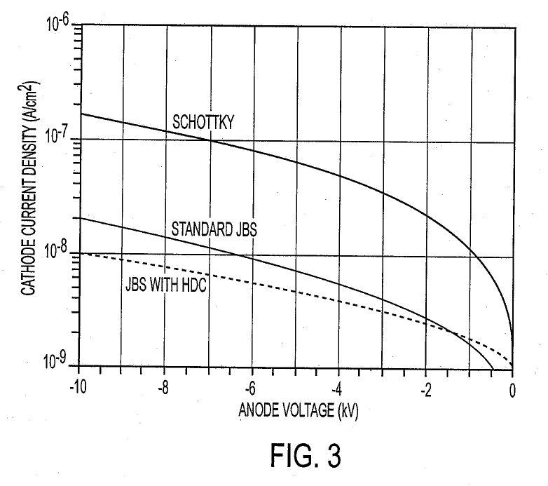

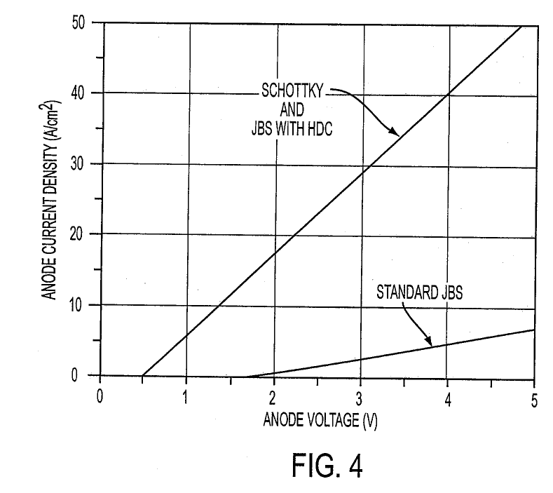

The advantages of this approach have been demonstrated through device simulation. Using the ATLAS two-dimensional device modeling software, the reverse blocking and forward resistance of three diodes were compared: (a) a standard Schottky diode, (b) a conventional JBS diode, and (c) the inventive JBS diode with highly-doped channel region. All have a drift doping and thickness (8×10¹⁴ ions cm⁻³, 80 •m) designed to block 10 kV in the reverse direction, and the two JBS structures are designed to have similar leakage currents for comparison. The conventional JBS diode has a p+ spacing of 3 •m, while a preferred embodiment of the inventive JBS diode structure has a spacing of 1.8 •m and a 3×10¹⁶ ions cm⁻³ and a 1.5 •m channel region. FIG. 3 shows the reverse leakage current in the three cases. It can be seen that both JBS diodes reduce the leakage current by an order of magnitude compared to the Schottky case. This correlates directly to the electric field at the Schottky interface at 10 kV; 1.83×10⁶ V/cm for the Schottky diode, 1.21×10⁶ V/cm for the conventional JBS, and 1.2×10⁶ V/cm for the JBS with HDC. However, as can be seen in FIG. 4, the conventional JBS structure suffers a serious degradation in forward current, while the proposed JBS structure maintains almost identical forward characteristics as the Schottky diode. In fact, in the later two cases, the channel resistance has been almost completely eliminated and the current is limited by the thick, lightly doped drift region.

In manufacturing devices according to the present invention, the various semiconductor regions may be formed or deposited according to any of the techniques known to the art. Similarly, dopant ions may be implanted or otherwise introduced by any suitable technique known to the art.

By way of non-limiting example, the drift and substrate regions may be formed by doping a wafer to a substantially uniform initial doping by adding appropriate ions to the growing boule. The substrate basal region may be differentiated from the drift region by the addition of further ions by diffusion or ion implantation. Ion implantation may be a preferred method because of its controlability. A first epitaxial layer of a semiconductor material may be grown on the drift layer. This first epitaxial layer may be the thickness of the channel region under the blocking well regions. The first layer may be doped as appropriate for a channel region by known methods, such as diffusion or ion implantation. A second epitaxial layer of a semiconductor material may be grown on the first layer. The second layer may be masked and differentially doped by, for example, ion implantation to define channel and well regions.

In the preferred embodiment, the substrate is formed by boule growth, the drift and channel regions by epitaxy, and the p wells by ion-implantation. However, alternative methods are possible.

As an example, a wafer may be provided having a thickness substantially the final thickness of the intended device. The wafer may be doped in the growing boule as appropriate for the drift region. Ions may be implanted into a first surface to a depth and concentration appropriate for a substrate basal region. Ions may be implanted into a second surface to a depth and concentration appropriate for a channel region. The p wells are then formed in the second surface, either by etch and epitaxial regrowth, or by ion-implantation.

An advantage of providing various semiconductor regions by epitaxial growth is that different semiconductor materials may comprise the various layers. Varying the semiconductor materials may aid in defining the electronic properties of the device.

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. For example, although the channel is shown extending to a depth greater than that of the wells and laterally completely beneath the wells such that the wells are completely spaced apart from the drift by a layer of channel, it will be appreciated that the JBS diode according to the present invention can be formed with a channel that extends at least substantially the depth of the wells, or below the depth of the wells, without extending laterally outward between the bottom of the wells and the drift layer. The barrier height of the Schottky barrier region may be tailored by varying the dopant concentration in the channel region immediately adjacent to the Schottky metal.

For pedagogic purposes, the JBS with highly doped channel region according to the present invention has been shown and described as a discrete diode. However, the JBS with highly doped channel region of the present invention may be incorporated into other devices using fabrication principles and methods known in the art. For example, the JBS with highly doped channel region of the present invention may be integrated as an anti-parallel diode into a power MOSFET or MESFET structure.

Accordingly, the description is not intended to limit the invention to the form disclosed herein. Also, it is intended that the appended claims be construed to include alternative embodiments.

1. A junction barrier Schottky device, comprising:
a semiconductor substrate including basal, drift, and channel regions doped with an ion of a first conductivity type, and a shielding region doped with an ion of a second conductivity type;
a Schottky barrier formed on said semiconductor substrate in contact with said channel and shielding regions; and
an electrode in electrical contact with said basal region and spaced apart from said drift region by said basal region;
wherein said drift region is spaced from said Schottky barrier by said channel region, and said shielding region is disposed around at least a portion of said channel region; and
wherein a dopant concentration in said channel region is higher than a dopant concentration in said drift region.

2. The junction barrier Schottky device according to claim 1, wherein a depth of said channel region is greater than a depth of said shielding region.

3. The junction barrier Schottky device according to claim 2, wherein said said channel region includes a portion that extends laterally beneath at least a portion of said shielding region.

4. A method of making a junction barrier Schottky device comprising:
forming basal, drift, and channel regions of a first conductivity type on a semiconductor substrate;
forming a shielding region of a second conductivity type in the semiconductor substrate around at least a portion of said channel region; and
forming a Schottky barrier on the channel and shielding regions;
wherein said step of forming basal, drift and channel regions includes forming the channel region with a dopant concentration higher than a dopant concentration of the drift region.

5. The method of making a junction barrier Schottky device according to claim 4, wherein said step of forming the channel region and said step of forming the shielding region are performed such that the channel region has a depth greater than a depth of said shielding region and extends laterally between said shielding region and said drift region.

6. The method of making a junction barrier Schottky device according to claim 4, wherein said basal region is a substrate formed by boule growth and said channel and drift regions are formed by a method selected from the group consisting of epitaxy and ion implantation.

7. The method of making a junction barrier Schottky device according to claim 4, wherein said drift region is a substrate formed by boule growth and said channel and basal regions are formed by a method selected from the group consisting of epitaxy and ion implantation.

8. The method of making a junction barrier Schottky device according to claim 4, wherein said shielding region is formed by ion implantation.

9. The method of making a junction barrier Schottky device according to claim 4, wherein said shielding region is formed by etching a trench in said channel region and providing an epitaxial layer in said trench.

10. The method of forming a junction barrier Schottky device according to claim 4, further comprising forming an ohmic region in contact with said shielding and Schottky regions.

11. A junction barrier Schottky device, comprising:
a semiconductor substrate including basal, drift, channel, and electrode contact regions doped with an ion of a first conductivity type, and a shielding region doped with an ion of a second conductivity type;
a Schottky barrier formed on said semiconductor substrate in contact with said channel and shielding regions; and
an electrode in electrical contact with said electrode contact region and spaced apart from said drift region by said electrode contact region;
wherein said drift region is spaced from said Schottky barrier by said channel region, and said shielding region is disposed around at least a portion of said channel region;
wherein a dopant concentration in said channel region is higher than a dopant concentration in said drift region; and
wherein a surface of said shielding, channel, drift, and electrode contact regions form a common co-planar surface.

12. The junction barrier Schottky device according to claim 11, wherein a depth of said channel region is greater than a depth of said shielding region.

13. The junction barrier Schottky device according to claim 11, wherein at least a portion of said shielding region is spaced apart from said drift region by said channel region.
